(19) United States
(12) Patent Application Publication
(10) Pub. No.: US 2025/0191920 A1
(43) Pub. Date: Jun. 12, 2025

(54) ELEMENT CHIP MANUFACTURING METHOD

(71) Applicant: Panasonic Intellectual Property Management Co., Ltd., Osaka (JP)

(72) Inventors: Shogo OKITA, HYOGO (JP); Atsushi HARIKAI, SAGA (JP); Hidehiko KARASAKI, HYOGO (JP)

(21) Appl. No.: 18/973,175

(22) Filed: Dec. 9, 2024

(30) Foreign Application Priority Data
Dec. 12, 2023 (JP) 2023-209595

(51) Int. Cl. H01L 21/268; H01L 21/78

(52) U.S. Cl. CPC H01L 21/268; H01L 21/78

(57) ABSTRACT

An element chip manufacturing method incudes: a preparation step of preparing a substrate including a semiconductor layer, a wiring layer, and a resin layer, and including a dicing region; a laser grooving step of irradiating a laser beam to the dicing region, to form an opening therein; and a plasma etching step. The laser grooving step includes a first step of irradiating a first laser beam having a first pulse width to the resin layer, to expose the wiring layer, and a second step of irradiating a second laser beam having a second pulse width shorter than the first pulse width to the wiring layer exposed in the first step, to expose the semiconductor layer. In the first step, the irradiation of the first laser beam to the resin layer corresponding to the dicing region is performed a plurality of times along the longitudinal direction of the dicing region.

### CROSS REFERENCE TO RELATED APPLICATION

The present application is based on and claims priority under 35 U.S.C. § 119 with respect to the Japanese Patent Application No. 2023-209595 filed on Dec. 12, 2023, of which entire content is incorporated herein by reference into the present application.

### TECHNICAL FIELD

The present disclosure relates to an element chip manufacturing method.

### TECHNICAL FIELD

Conventionally, there has been known an element chip manufacturing method in which a substrate is diced into a plurality of element chips by plasma etching (e.g., Patent Literature 1: JP2005-191039A). The element chip manufacturing method of Patent Literature 1 includes a step of forming a mask layer on a circuit-forming surface of a substrate on which a plurality of semiconductor elements are formed, a step of removing the mask layer in a dicing region that divides adjacent semiconductor elements from each other by laser beam irradiation, and a step of removing the substrate corresponding to the dicing region by plasma etching, to obtain a plurality of element chips.

According to the element chip manufacturing method of Patent Literature 1, however, unevenness may occur in some cases at the edge of the opening formed during laser beam irradiation, and this may result in a reduced smoothness of the side surfaces of element chips to be obtained, causing the die strength of the element chips to decrease. Under such circumstances, one object of the present disclosure is to improve the die strength of the element chips.

### SUMMARY

One aspect of the present disclosure relates to an element chip manufacturing method. The manufacturing method includes: a preparation step of preparing a substrate including a semiconductor layer having a first principal surface and a second principal surface, a wiring layer formed on the semiconductor layer on the first principal surface side, and a resin layer formed on the wiring layer, the substrate including a plurality of element regions, and a dicing region defining the element regions; a laser grooving step of irradiating a laser beam to the dicing region from the first principal surface side, to form an opening that exposes the semiconductor layer in the dicing region; and a plasma etching step of etching the semiconductor layer exposed from the opening with plasma, to obtain a plurality of element chips, wherein the laser grooving step includes a first step of irradiating a first laser beam having a first pulse width to the resin layer, to remove the resin layer corresponding to the dicing region, and expose the wiring layer, and a second step of irradiating a second laser beam having a second pulse width shorter than the first pulse width to the wiring layer exposed in the first step, to remove the wiring layer corresponding to the dicing region and expose the semiconductor layer, and in the first step, the irradiation of the first laser beam to the resin layer corresponding to the dicing region is performed a plurality of times along a longitudinal direction of the dicing region.

According to the present disclosure, it is possible to improve the die strength of the element chips.

### BRIEF DESCRIPTION OF THE DRAWINGS

FIG. 1 is a sectional view for explaining a preparation step.

FIG. 2 is a sectional view for explaining a first step of a laser grooving step.

FIG. 3 is a plan view schematically showing a plurality of first irradiation planned lines.

FIG. 4 is a sectional view for explaining a second step of the laser grooving step.

FIG. 5 is a plan view schematically showing a plurality of second irradiation planned lines.

FIG. 6 is a sectional view for explaining a third step of the laser grooving step.

FIG. 7 is a sectional view for explaining a plasma etching step.

FIG. 8 is a schematic diagram of an example of a plasma processing apparatus.

### DETAILED DESCRIPTION

Description will be given below of an embodiment of an element chip manufacturing method according to the present disclosure by way of examples. The present disclosure, however, is not limited to the examples described below. In the description below, specific numerical values and materials are exemplified in some cases, but other numerical values and materials may be adopted as long as the effects of the present disclosure can be achieved.

The element chip manufacturing method according to the present disclosure is a method for obtaining a plurality of element chips by singulating a substrate by plasma etching. The element chip manufacturing method according to the present disclosure includes a preparation step, a laser grooving step, and a plasma etching step.

In the preparation step, a substrate is prepared that includes a semiconductor layer having a first principal surface and a second principal surface, a wiring layer formed on the first principal surface side of the semiconductor layer, and a resin layer formed on the wiring layer. The substrate includes a plurality of element regions, and a dicing region defining the element regions. The semiconductor material contained in the semiconductor layer is not particularly limited, and may be, for example, Si, SiC, GaN, or GaAs. The wiring layer may contain, for example, an insulating film of SiO₂, SiN, SiCN, or the like, and a metal of Cu, Al, or the like. The shape of each element region is not particularly limited, and may be, for example, a rectangle, a polygon, or a circle. The width of the dicing region is also not particularly limited, and may be set as appropriate according to the purpose. The resin layer may contain a water-soluble or water-insoluble resin material. The resin layer may have any thickness as long as it is thick enough not to be completely removed in the plasma etching step. An example of the water-insoluble resin material is a photoresist material. The resin layer may be formed on the wiring layer by, for example, spray coating or spin coating.

In the laser grooving step, a laser beam is irradiated to the dicing region from the first principal surface side, to form an opening that exposes the semiconductor layer in the dicing region. That is, in the laser grooving step, the resin layer and the wiring layer corresponding to the dicing region are removed by the laser beam irradiation. At this time, according to the conventional method in which the resin layer and the wiring layer are simultaneously removed, unevenness may occur in some cases at the edge of the opening. This is presumably because a shock wave will generate between the resin layer and the wiring layer during the laser beam irradiation, which causes the resin layer adjacent to the resin layer in the dicing region to be partially peeled off from the wiring layer. With the unevenness at the edge of the opening, if any, the smoothness of the side surfaces of the element chips may be reduced, and eventually, the die strength of the element chips may decrease.

In this regard, the laser grooving step of the present disclosure has a first step in which the resin layer is mainly removed and a second step in which the wiring layer is mainly removed, and through the both steps, the aforementioned opening is formed. More specifically, in the first step, a first laser beam having a first pulse width is irradiated to the resin layer, to remove the resin layer corresponding to the dicing region and expose the wiring layer. In the second step, a second laser beam having a second pulse width shorter than the first pulse width is irradiated to the wiring layer exposed in the first step, to remove the wiring layer corresponding to the dicing region and expose the semiconductor layer. The first pulse width may be, for example, a pulse width on the order of nanoseconds. The second pulse width may be, for example, a pulse width on the order of picoseconds or femtoseconds.

In this way, by using the first laser beam having a relatively long pulse width (first pulse width) to remove the resin layer, the peak value of the laser intensity can be kept low, and the shock wave generated between the resin layer and the wiring layer can be weakened, which as a result can prevent unintended peeling off of the resin layer. However, a too long pulse width of the first laser beam (e.g., a pulse width on the order of milliseconds) is not preferable because the laser's heat will excessively melt the resin layer. Therefore, the first pulse width is preferably a pulse width of the order of submilliseconds at most. Furthermore, by using the second laser beam having a relatively short pulse width (second pulse width) to remove the wiring layer, the thermal effect on the semiconductor layer under the wiring layer can be suppressed, and undesirable influences, such as thermal distortion, on the resulting element chips can be suppressed.

Furthermore, in the first step of the present disclosure, the irradiation of the first laser beam to the resin layer corresponding to the dicing region is performed a plurality of times along the longitudinal direction of the dicing region. In this way, instead of removing the resin layer by the irradiation of the first laser beam performed once, the resin layer is removed by the irradiation of the first laser beam performed a plurality of times. This allows for lowering the laser intensity per irradiation, thereby making it possible to further weaken the shock wave generated between the resin layer and the wiring layer. That is, unintended peeling off of the resin layer can be further suppressed. The longitudinal direction of the dicing region refers to the extension direction of the dicing region that extends so as to divide the adjacent element regions.

In the plasma etching step, the semiconductor layer exposed in the opening is etched with plasma, to obtain a plurality of element chips. The respective element chips may correspond to the above element regions. The plasma etching can be performed using the resin layer as a mask. As described above, according to the laser grooving step of the present disclosure, the unintended peeling off of the resin layer can be suppressed. Therefore, in the element chips obtained by plasma etching using the resin layer as a mask, the sides thereof will have a high degree of smoothness. Thus, the die strength of the element chips can be improved.

The irradiation of the first laser beam in the first step may include irradiating the first laser beam along each of a plurality of first irradiation planned lines that are set apart from each other in the width direction of the dicing region and extend in the longitudinal direction of the dicing region. The width direction of the dicing region refers to the direction perpendicular to the longitudinal direction of the dicing region (or the direction in which adjacent element regions face each other). For example, the plurality of the first irradiation planned lines may include two first irradiation planned lines near the ends in the width direction, that is, a pair of first irradiation planned lines positioned outermost in the width direction of the dicing region (hereinafter also referred to as first outermost irradiation planned lines), and at least one (preferably one) first irradiation planned line positioned between the two first irradiation planned lines.

The irradiation of the first laser beam along the first irradiation planned lines in the first step may begin with an irradiation along the first irradiation planned line closest to an end of the dicing region in the width direction. According to this configuration, the resin layer adjacent to the element regions is removed immediately after the start of the first step (i.e., before the irradiation of the first laser beam along the first irradiation planned line relatively far from the end of the dicing region) by the irradiation of the first laser beam along the first irradiation planned line closest to the end of the dicing region. Therefore, the thermal effect by the subsequent irradiation of the first laser beam is unlikely to reach the element regions. When there are two first irradiation planned lines closest to the ends of the dicing region in the width direction, the first laser beam may be irradiated along one of the first irradiation planned lines, and then, the first laser beam may be irradiated along the other first irradiation planned line, or the first laser beam may be simultaneously irradiated along both the first irradiation planned lines.

The beam width of the first laser beam irradiated along the first irradiation planned line closest to an end of the dicing region in the width direction may be smaller than the beam width of the first laser beam irradiated along the first irradiation planned line closer to the center of the dicing region in the width direction. For example, the beam width of the former may be 1 μm or more and 6 μm or less, and the beam width of the latter may be 10 μm or more and 20 μm or less.

The irradiation of the first laser beam along the first irradiation planned line closest to an end of the dicing region in the width direction in the first step may be performed a plurality of times along the same first irradiation planned line. In this case, as compared to the case where the irradiation of the first laser beam along the first irradiation planned line is completed in once, the peak value of the laser intensity can be kept low, and the shock wave generated between the resin layer and the wiring layer can be weakened, which as a result can prevent unintended peeling off of the resin layer. In addition, the thermal effect on the element regions due to the irradiation of the first laser beam can be suppressed. The number of times of the irradiation of the first laser beam along the same first irradiation planned line may be, for example, two or more and five or less.

The irradiation of the first laser beam in the first step may be performed a plurality of times along a same first irradiation planned line set so as to extend in the longitudinal direction of the dicing region. In this case, as compared to the case where the irradiation of the first laser beam along the first irradiation planned line is completed in once, the peak value of the laser intensity can be kept low, and the shock wave generated between the resin layer and the wiring layer can be weakened, which as a result can prevent unintended peeling off of the resin layer. The number of times of the irradiation of the first laser beam along the same first irradiation planned line may be, for example, two or more and five or less.

The first laser beam may be a UV laser or an infrared laser. In this case, the resin layer can to be efficiently removed with the first laser beam, especially when the resin layer contains a water-soluble resin material.

The irradiation of the second laser beam in the second step may include irradiating the second laser beam along each of a plurality of second irradiation planned lines that are set apart from each other in the width direction of the dicing region and extend in the longitudinal direction of the dicing region. For example, the plurality of the second irradiation planned lines may include two second irradiation planned lines near the ends in the width direction, that is, a pair of second irradiation planned lines positioned outermost in the width direction of the dicing region (hereinafter also referred to as second outermost irradiation planned lines), and at least one second irradiation planned line positioned between the two second irradiation planned lines. The second irradiation planned lines may or may not overlap the first irradiation planned lines.

The first irradiation planned lines and the second irradiation planned lines may be set such that a second region sandwiched between a pair of the second outermost irradiation planned lines is within a first region sandwiched between a pair of the first outermost irradiation planned lines. This can suppress unfavorable occurrences induced by the irradiation of the second laser beam, such as the ablation of the resin layer, and the partial peeling of the resin layer from the wiring layer.

The irradiation of the second laser beam along the second irradiation planned lines in the second step may begin with an irradiation along the second irradiation planned line closest to an end of the dicing region in the width direction. According to this configuration, the wiring layer adjacent to the element regions is removed immediately after the start of the second step (i.e., before the irradiation of the second laser beam along the second irradiation planned line relatively far from the end of the dicing region) by the irradiation of the second laser beam along the second irradiation planned line closest to the end of the dicing region. Therefore, the thermal effect by the subsequent irradiation of the second laser beam is unlikely to reach the element regions. When there are two second irradiation planned lines closest to the ends of the dicing region in the width direction, the second laser beam may be irradiated along one of the second irradiation planned lines, and then, the second laser beam may be irradiated along the other second irradiation planned line, or the second laser beam may be simultaneously irradiated along both second irradiation planned lines.

The plurality of the second irradiation planned lines may include two second irradiation planned lines close to the ends of the dicing region in the width direction, and at least two second irradiation planned lines that are set between the two second irradiation planned lines. According to this configuration, as compared to the case where only one second irradiation planned line is set in a region corresponding to at least two second irradiation planned lines, the thermal effect on the semiconductor layer (esp., the semiconductor layer in the element regions) can be suppressed. The irradiation of the second laser beam along at least two second irradiation planned lines may be performed sequentially one by one, or plural by plural, or may be performed all simultaneously. In the former case of performing sequentially, the thermal effect on the semiconductor layer can be further suppressed, while in the latter case of performing all simultaneously, the tact time for manufacturing element chips can be shortened.

The irradiation of the second laser beam along at least two second irradiation planned lines may be performed a plurality of times along the same second irradiation planned lines. In this case, as compared to the case where the irradiation of the second laser beam along the second irradiation planned lines is completed in once, the peak value of the laser intensity can be kept low, and the thermal effect on the semiconductor layer (esp., the semiconductor layer in the element regions) under the wiring layer can be further suppressed. The number of times of the irradiation of the second laser beam along the same second irradiation planned lines may be, for example, two or more and five or less.

As described above, according to the present disclosure, the die strength of the element chips can be improved by adopting the laser grooving step having predetermined first and second steps.

In the following, examples of the element chip manufacturing method according to the present disclosure will be specifically described with reference to the drawings. The steps as described above can be applied to the steps of the below-described examples of the element chip manufacturing method. The steps of the below-described examples of the element chip manufacturing method can be modified based on the description above. The matters described below may be applied to the above embodiments. Of the steps of the below-described examples of the element chip manufacturing method, the steps which are not essential to the element chip manufacturing method according to the present disclosure may be omitted. The figures below are schematic and not intended to correctly reflect the shape and the number of the actual members.

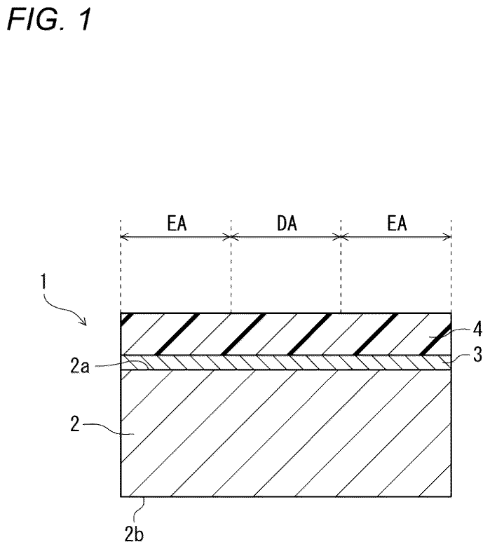

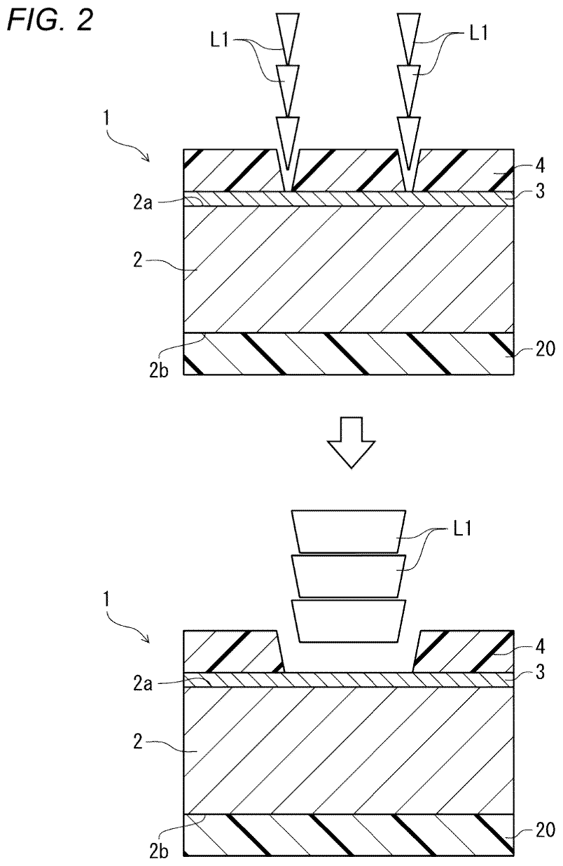

The element chip manufacturing method of the present embodiment is a method of obtaining a plurality of element chips by singulating a substrate by plasma etching. As shown in FIGS. 1 to 7, the element chip manufacturing method includes a preparation step, a laser grooving step, and a plasma etching step. The laser grooving step and the plasma etching step may be performed, as shown in FIGS. 2 to 7, while a substrate 1 is held on a conveying carrier having a holding tape 20 and a frame (not shown) supporting the holding tape 20.

In the preparation step, as shown in FIG. 1, the substrate 1 is prepared that includes a semiconductor layer 2 having a first principal surface 2a and a second principal surface 2b, a wiring layer 3 formed on the first principal surface 2a side of the semiconductor layer 2, and a resin layer 4 formed on the wiring layer 3. The substrate 1 includes a plurality of element regions EA, and a dicing region DA that defines the element regions EA. The resin layer 4 of the present embodiment includes a water-soluble resin material, but is not limited thereto. In the laser grooving step, as shown in FIGS. 2 to 6, laser beams L1 and L2 are irradiated to the dicing region DA from the first principal surface 2a side, to form an opening 5 that exposes the semiconductor layer 2 in the dicing region DA. The laser grooving step has a first step, a second step, and a third step.

In the first step, as shown in FIG. 2, the first laser beam LI having a first pulse width (e.g., a pulse width on the order of nanoseconds) is irradiated to the resin layer 4, to remove the resin layer 4 corresponding to the dicing region DA and expose the wiring layer 3. In the first step, the irradiation of the first laser beam L1 to the resin layer 4 corresponding to the dicing region DA is performed a plurality of times along the longitudinal direction of the dicing region DA (the direction perpendicular to the paper surface in FIG. 2). The first laser beam L1 in the present embodiment is a UV laser, but not limited thereto.

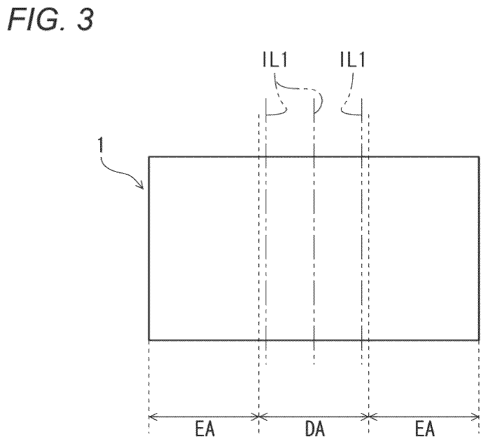

Specifically, the irradiation of the first laser beam L1 in the first step includes irradiating the first laser beam L1 along each of a plurality of (three, in this example) first irradiation planned lines IL1 (shown by two-dot-dash lines in FIG. 3) that are set apart from each other in the width direction of the dicing region DA (left-right direction in FIG. 2) and extend in the longitudinal direction of the dicing region DA.

Furthermore, the irradiation of the first laser beam L1 along the plurality of the first irradiation planned lines IL1 in the first step begins with an irradiation along the first irradiation planned lines IL1 (two first irradiation planned lines IL1 on the left and right in FIG. 3) that are closest to the ends of the dicing region DA in the width direction. In the present embodiment, the irradiations along the two first irradiation planned lines IL1 are performed simultaneously, but not limited thereto.

Moreover, the irradiation of the first laser beam L1 along the first irradiation planned lines IL1 closest to the ends of the dicing region DA in the first step is performed a plurality of times (three times, in this example) along the same first irradiation planned lines IL1. In FIG. 2, three first laser beams L1 are vertically lined up, which means that the first laser beam L1 is irradiated three times.

The irradiation of the first laser beam L1 along the plurality of the first irradiation planned lines IL1 in the first step may be performed, with the beam shape of the first laser beam L1 changed. For example, as shown in FIG. 2, the irradiation of the first laser beam L1 along the first irradiation planned lines IL1 closest to the ends of the dicing region DA in the width direction in the first step may be performed, with the beam diameter of the first laser beam L1 set relatively narrow, and then, the irradiation of the first laser beam L1 along the first irradiation planned line IL1 near the center of the dicing region DA in the width direction, with the beam diameter of the first laser beam L1 set relatively wide.

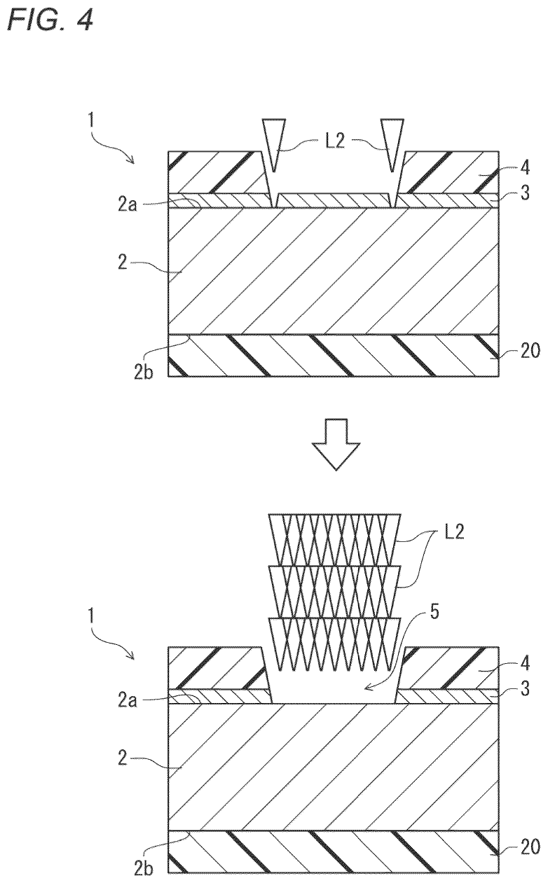

In the second step, as shown in FIG. 4, the second laser beam L2 having a second pulse width (e.g., a pulse width on the order of femtoseconds) shorter than the first pulse width is irradiated to the wiring layer 3 exposed in the first step, to remove the wiring layer 3 corresponding to the dicing region DA and expose the semiconductor layer 2. In the second step, the irradiation of the second laser beam L2 to the wiring layer 3 corresponding to the dicing region DA is performed a plurality of times along the longitudinal direction of the dicing region DA (the direction perpendicular to the paper surface in FIG. 4).

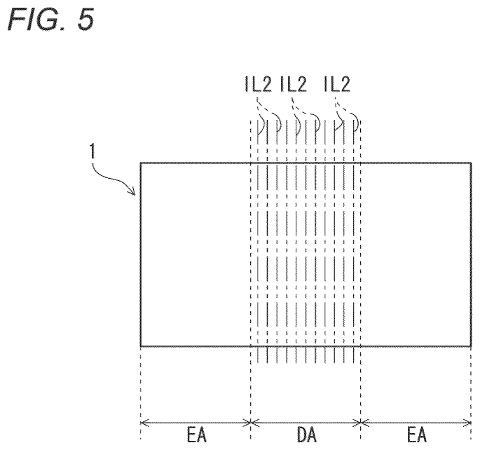

Specifically, the irradiation of the second laser beam L2 in the second step includes irradiating the second laser beam L2 along each of a plurality of (eleven, in this example) second irradiation planned lines IL2 (shown by two-dot-dash lines in FIG. 5) that are set apart from each other in the width direction of the dicing region DA (left-right direction in FIG. 4) and extend in the longitudinal direction of the dicing region DA.

The first irradiation planned lines IL1 and the second irradiation planned lines IL2 may be set such that a second area sandwiched between a pair of the second irradiation planned lines IL2 (a pair of the second outermost irradiation planned lines) positioned outermost in the width direction of the dicing region DA is within a first region sandwiched between a pair of the first irradiation planned lines IL1 (a pair of the first outermost irradiation planned lines) positioned outermost in the width direction of the dicing region DA.

Furthermore, the irradiation of the second laser beam L2 along the plurality of the second irradiation planned lines IL2 in the second step begins with an irradiation along the second irradiation planned lines IL2 closest to the ends of the dicing region DA in the width direction (two second irradiation planned lines IL2 on the left and the right in FIG. 5). In the present embodiment, the irradiations along the two second irradiation planned lines IL2 are performed simultaneously, but not limited thereto.

The second irradiation planned lines IL2 include two second irradiation planned lines IL2 close to the ends of the dicing region DA in the width direction and at least two (nine, in this example) second irradiation planned lines IL2 between the two second irradiation planned lines IL2. In the present embodiment, the irradiations of the second laser beam L2 along the nine second irradiation planned lines IL2 are performed all simultaneously, but not limited thereto. Moreover, the irradiation of the second laser beam L2 along the nine second irradiation planned lines IL2 is performed a plurality of times (three times, in this example) along the same second irradiation planned lines IL2. In FIG. 4, three second laser beams L2 are vertically line up, which means that the second laser beam L2 is irradiated three times.

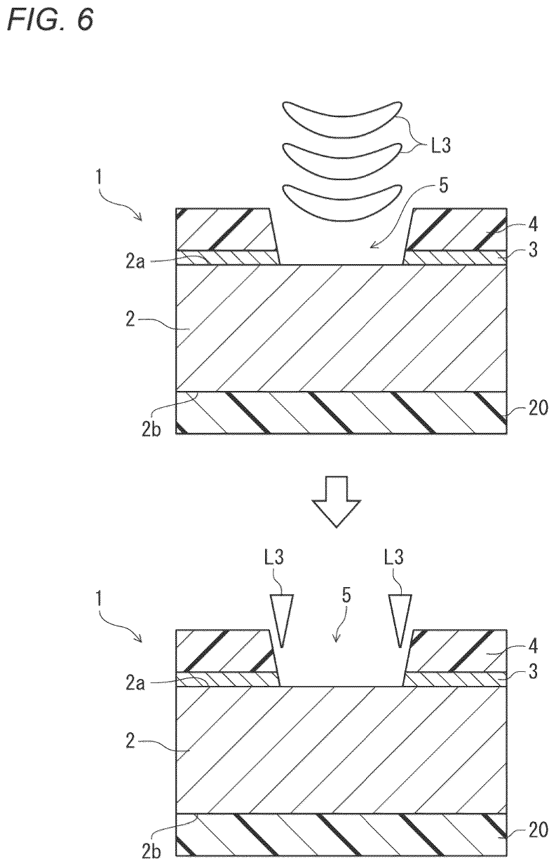

In the third step, as shown in FIG. 6, a third laser beam L3 having lower energy than the first laser beam L1 and the second laser beam L2 is irradiated to the exposed surface (including the surface of the semiconductor layer 2 and the side surfaces of the resin layer 4 and the wiring layer 3) in the opening 5, to remove the deposits (debris) having adhered to the exposed surface in the first and second steps. In the third step, the irradiation of the third laser beam L3 to the exposed surface is performed a plurality of times along the longitudinal direction of the dicing region DA (the direction perpendicular to the paper surface in FIG. 6).

Specifically, the irradiation of the third laser beam L3 in the third step includes irradiating the third laser beam L3 along each of a plurality (three, in this example) of third irradiation planned lines (not shown) that are set apart from each other in the width direction of the dicing region DA (left-right direction in FIG. 6) and extend in the longitudinal direction of the dicing region DA.

Furthermore, the irradiation of the third laser beam L3 along the plurality of the third irradiation planned lines in the third step begins with an irradiation along the third irradiation planned line near the center of the dicing region DA in the width direction. The third laser beam L3 irradiated along the third irradiation planned line near the center preferably has a third pulse width shorter than the first pulse width (e.g., a pulse width on the order of femtoseconds), and preferably has a width dimension of 80% or more of the width dimension of the dicing region DA. Moreover, the irradiation of the third laser beam L3 is preferably performed a plurality of times (three times, in this example) along the same third irradiation planned line. On the other hand, the third laser beam L3 irradiated along the third irradiation planned lines near the ends of the dicing region DA in the width direction in the third step preferably has a width dimension of 20% or less of the width dimension of the dicing region DA, and performing this irradiation at least once suffices.

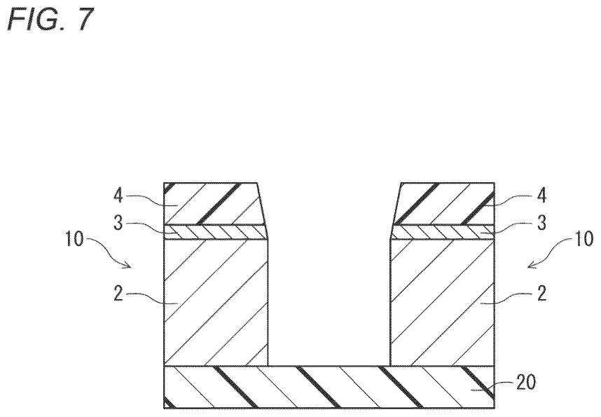

In the plasma etching step, as shown in FIG. 7, the semiconductor layer 2 exposed in the opening 5 is etched with plasma, so that a plurality of element chips 10 respectively corresponding to the element regions EA are obtained. The respective element chips 10 correspond to the element regions EA of the substrate 1. The plasma etching may be performed using, for example, the Bosch process.

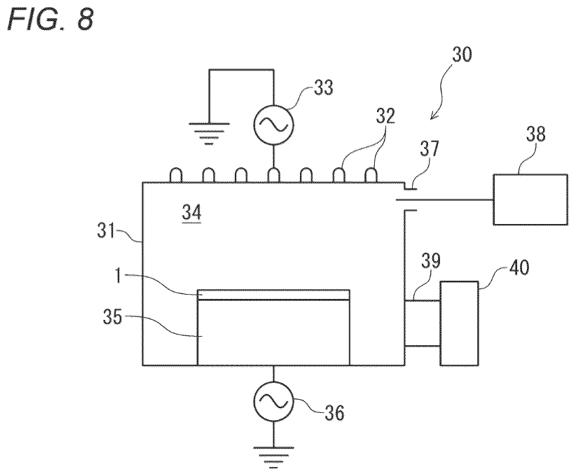

In the plasma etching step, a plasma processing apparatus 30 (plasma etching apparatus 30) as illustrated in FIG. 8 may be used. The plasma processing apparatus 30 includes a chamber 31 having a dielectric window at the top and defining a processing room 34, an antenna 32 serving as an upper electrode and disposed on the upper side of the chamber 31, a first high-frequency power source 33 electrically connected to the antenna 32, a stage 35 serving as a lower electrode for placing the substrate 1 thereon and disposed on the bottom side of the processing room 34, and a second high-frequency power source 36 electrically connected to the stage 35. A gas inlet 37 provided in the chamber 31 is fluidly connected to a raw material gas source 38. An exhaust port 39 provided in the chamber 31 is fluidly connected to a vacuum evacuation section 40 including a vacuum pump.

In the plasma processing apparatus 30 as illustrated in FIG. 8, after the substrate 1 is placed on the stage 35, the pressure inside the processing room 34 is reduced with the vacuum evacuation section 40, and a raw material gas is introduced into the processing room 34 from the raw material gas source 38. Then, a high frequency power is supplied from the first high-frequency power source 33 to the antenna 32, to generate plasma in the processing room 34 so that the substrate 1 is irradiated with the plasma. The physicochemical action of the radicals and ions in the plasma can remove the semiconductor layer 2 exposed at the bottom of the opening 5. The collision speed of the radicals and ions with the substrate 1 can be controlled by supplying a high frequency power from the second high-frequency power source 36 to the stage 35.

### Supplementary Notes

The above description of embodiments discloses the following techniques.

### (Technique 1)

An element chip manufacturing method, comprising:
a preparation step of preparing a substrate including a semiconductor layer having a first principal surface and a second principal surface, a wiring layer formed on the semiconductor layer on the first principal surface side, and a resin layer formed on the wiring layer, the substrate including a plurality of element regions, and a dicing region defining the element regions;
a laser grooving step of irradiating a laser beam to the dicing region from the first principal surface side, to form an opening that exposes the semiconductor layer in the dicing region; and
a plasma etching step of etching the semiconductor layer exposed from the opening with plasma, to obtain a plurality of element chips, wherein the laser grooving step includes
a first step of irradiating a first laser beam having a first pulse width to the resin layer, to remove the resin layer corresponding to the dicing region, and expose the wiring layer, and
a second step of irradiating a second laser beam having a second pulse width shorter than the first pulse width to the wiring layer exposed in the first step, to remove the wiring layer corresponding to the dicing region and expose the semiconductor layer, and
in the first step, the irradiation of the first laser beam to the resin layer corresponding to the dicing region is performed a plurality of times along a longitudinal direction of the dicing region.

### (Technique 2)

The element chip manufacturing method according to technique 1, wherein the irradiation of the first laser beam in the first step includes irradiating the first laser beam along each of a plurality of first irradiation planned lines that are set apart from each other in a width direction of the dicing region and extend in the longitudinal direction of the dicing region.

### (Technique 3)

The element chip manufacturing method according to technique 2, wherein the irradiation of the first laser beam along the first irradiation planned lines in the first step begins with an irradiation along the first irradiation planned line closest to an end of the dicing region in the width direction.

### (Technique 4)

The element chip manufacturing method according to technique 3, wherein the irradiation of the first laser beam along the first irradiation planned line closest to the end of the dicing region in the width direction in the first step is performed a plurality of times along the same first irradiation planned line.

### (Technique 5)

The element chip manufacturing method according to any one of techniques 2 to 4, wherein
the irradiation of the second laser beam in the second step includes irradiating the second laser beam along each of a plurality of second irradiation planned lines that are set apart from each other in the width direction of the dicing region and extend in the longitudinal direction of the dicing region, and
the first irradiation planned lines and the second irradiation planned lines are set such that a second region sandwiched between a pair of the second irradiation planned lines positioned outermost in the width direction of the dicing region is within a first region sandwiched between a pair of the first irradiation planned lines positioned outermost in the width direction of the dicing region.

### (Technique 6)

The element chip manufacturing method according to technique 1, wherein the irradiation of the first laser beam in the first step is performed a plurality of times along a same first irradiation planned line set so as to extend in the longitudinal direction of the dicing region.

### (Technique 7)

The element chip manufacturing method according to any one of techniques 1 to 6, wherein the first laser beam is a UV laser or an infrared laser.

The present disclosure is applicable to an element chip manufacturing method.

### REFERENCE NUMERALS

1: substrate
2: semiconductor layer
2a: first principal surface
2b: second principal surface
3: wiring layer
4: resin layer
5: opening
10: element chip
20: holding tape
30: plasma processing apparatus
31: chamber
32: antenna
33: first high-frequency power source
34: processing room
35: stage
36: second high-frequency power source
37: gas inlet
38: raw material gas source
39: exhaust port
40: vacuum evacuation section
DA: dicing region
EA: element region
IL1: first irradiation planned line
IL2: second irradiation planned line
L1: first laser beam
L2: second laser beam
L3: third laser beam

What is claimed is:

1. An element chip manufacturing method, comprising:
a preparation step of preparing a substrate including a semiconductor layer having a first principal surface and a second principal surface, a wiring layer formed on the semiconductor layer on the first principal surface side, and a resin layer formed on the wiring layer, the substrate including a plurality of element regions, and a dicing region defining the element regions;
a laser grooving step of irradiating a laser beam to the dicing region from the first principal surface side, to form an opening that exposes the semiconductor layer in the dicing region; and
a plasma etching step of etching the semiconductor layer exposed from the opening with plasma, to obtain a plurality of element chips, wherein
the laser grooving step includes
a first step of irradiating a first laser beam having a first pulse width to the resin layer, to remove the resin layer corresponding to the dicing region, and expose the wiring layer, and
a second step of irradiating a second laser beam having a second pulse width shorter than the first pulse width to the wiring layer exposed in the first step, to remove the wiring layer corresponding to the dicing region and expose the semiconductor layer, and
in the first step, the irradiation of the first laser beam to the resin layer corresponding to the dicing region is performed a plurality of times along a longitudinal direction of the dicing region.

2. The element chip manufacturing method according to claim 1, wherein the irradiation of the first laser beam in the first step includes irradiating the first laser beam along each of a plurality of first irradiation planned lines that are set apart from each other in a width direction of the dicing region and extend in the longitudinal direction of the dicing region.

3. The element chip manufacturing method according to claim 2, wherein the irradiation of the first laser beam along the first irradiation planned lines in the first step begins with an irradiation along the first irradiation planned line closest to an end of the dicing region in the width direction.

4. The element chip manufacturing method according to claim 3, wherein the irradiation of the first laser beam along the first irradiation planned line closest to the end of the dicing region in the width direction in the first step is performed a plurality of times along the same first irradiation planned line.

5. The element chip manufacturing method according to claim 2, wherein
the irradiation of the second laser beam in the second step includes irradiating the second laser beam along each of a plurality of second irradiation planned lines that are set apart from each other in the width direction of the dicing region and extend in the longitudinal direction of the dicing region, and
the first irradiation planned lines and the second irradiation planned lines are set such that a second region sandwiched between a pair of the second irradiation planned lines positioned outermost in the width direction of the dicing region is within a first region sandwiched between a pair of the first irradiation planned lines positioned outermost in the width direction of the dicing region.

6. The element chip manufacturing method according to claim 1, wherein the irradiation of the first laser beam in the first step is performed a plurality of times along a same first irradiation planned line set so as to extend in the longitudinal direction of the dicing region.

7. The element chip manufacturing method according to claim 1, wherein the first laser beam is a UV laser or an infrared laser.
